(19) United States
(12) Patent Application Publication
(10) Pub. No.: US 2023/0345629 A1
(43) Pub. Date: Oct. 26, 2023

(54) PCB STIFFENING STRUCTURE TO PREVENT WARPING

(71) Applicant: DELL PRODUCTS L.P., Round Rock, TX (US)

(72) Inventors: Sandor Farkas, Round Rock, TX (US); Bhyrav Mutnury, Austin, TX (US); Daniel J. Carey, Austin, TX (US)

(21) Appl. No.: 17/729,800

(22) Filed: Apr. 26, 2022

(51) Int. Cl. H05K 1/02; H05K 1/11

(52) U.S. Cl. CPC H05K 1/0271; H05K 1/115; H05K 1/0366

(57) ABSTRACT

A printed circuit board (PCB) includes a metal layer and a via. The via is coupled to a portion of the metal layer. The portion of the metal layer forms a flange of a beam structure in the PCB. The via forms a web of the beam structure in the PCB.

### FIELD OF THE DISCLOSURE

This disclosure generally relates to information handling systems, and more particularly relates to providing a stiffening structure in a PCB to prevent warping.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A printed circuit board (PCB) may include a metal layer and a via. The via may be coupled to a portion of the metal layer. The portion of the metal layer may form a flange of a beam structure in the PCB. The via may form a web of the beam structure in the PCB.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates side views of a PCB with a stiffening structure according to an embodiment of the current disclosure;

FIG. 2 illustrates side views of PCBs with stiffening structures according to an embodiment of the current disclosure;

FIG. 3 illustrates top views of PCBs with stiffening structures according to an embodiment of the current disclosure; and

FIG. 4 is a block diagram illustrating a generalized information handling system according to another embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

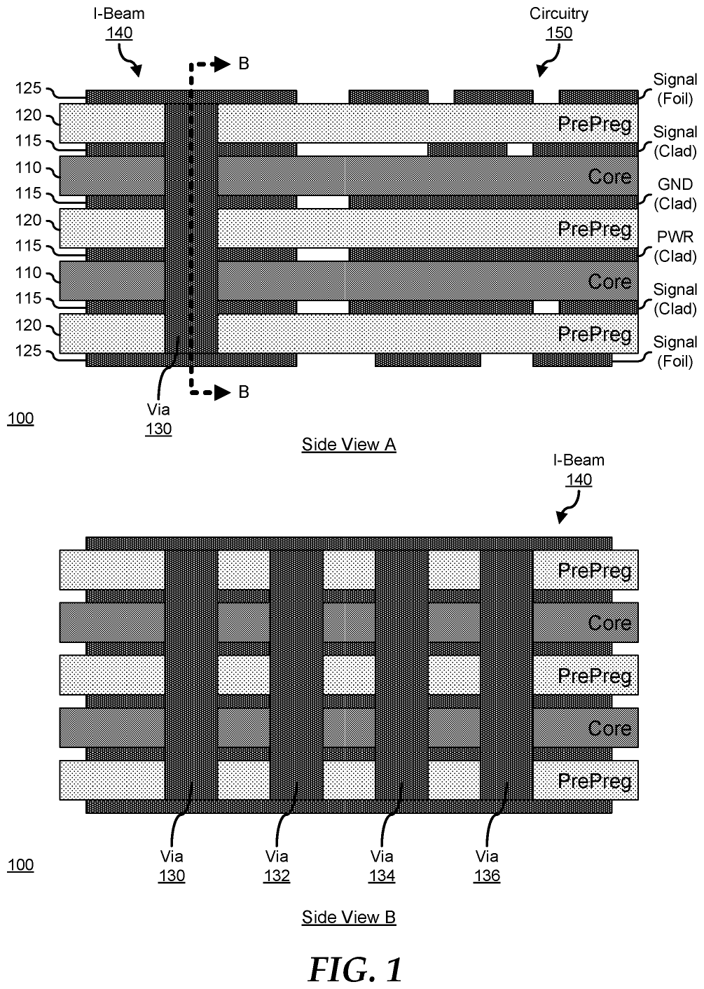

FIG. 1 illustrates side views of a printed circuit board (PCB) 100 with an I-beam stiffening structure 140 (hereinafter “I-beam 140”), and circuitry 150. PCB 100 includes core layers 110 with copper cladding layers 115 on both sides of the core layers, layers of fiber pre-impregnated with a resin material, commonly referred to as prepreg 120, and copper foil layers 125. PCB 100 is provided with a circuitry portion 150 that represents the patterned circuit traces in copper layers 115 and 125, upon which components are connected for performing a particular function.

PCB 100 includes six copper layers 115 and 125, and hence will be referred to as a 6-layer PCB. Other layer counts may be utilized in conjunction with the teaching of the current disclosure, as needed or desired. Here, one or more inner metal layer (typically one of copper cladding layers 115) is provided as a power plane, one or more inner metal layer (typically another one of the copper cladding layers) is provided as a ground plane, and the remaining metal layers (typically any remaining copper cladding layers and copper foil layers 125) are provided for patterned signal traces that may be interconnected between the signal layers by circuit vias (not shown). The details of PCB manufacture, and particularly the forming of circuitry such as circuitry 140, and of component assembly on a PCB are known in the art and will not be further described herein, except as needed to illustrate the current embodiments.

PCBs such as PCB 100 are typically expected to provide rugged performance over a wide range of environmental conditions and for long durations of time. However, thermal cycles in the PCB manufacturing process, the component assembly process, and subsequent operation may result in warpage of the PCB. Such warpage may increase over time, or be exacerbated by local heat sources on the PCB, such as processors, memory devices, graphics processor units (GPUs), and the like. Warpage experienced by the PCB prior to the component assembly process may result in poor fit up of the components to be assembled thereon, and hence to post-assembly test failures. Also, warpage experienced by the PCB after the component assembly process may induce stress on solder joints between components and the PCB which may, over time, result in fractured solder joints that cause reliability issues and system failures.

I-beam 140 represents a structural member formed in the manufacturing of PCB 100. Here, copper layers 115 and 125 are interconnected with plated through-hole vias 130, 132, 134, and 136 that form a beam structure on the edge of PCB 100. Vias 130, 132, 134, and 136 operate as a web, i.e., a vertical member, of an I-beam structure that are bound to the metal of copper layers 115 and 125 that form the flanges, i.e., the horizonal members, of the I-beam structure. In a particular embodiment, vias 130, 132, 134, and 136 are evenly spaced along the edge of PCB 100 to provide equal rigidity along the entire length of the edge. In another embodiment, one or more of vias 130, 132, 134, and 136 are spaced differently from the other vias. Here, it may be understood that PCB 100 has need of greater rigidity in a particular portion of the PCB, such as proximate to a CPU, a memory device, a GPU, or the like. Hence, in such a portion of PCB 100, greater rigidity may be provided by closer spaced vias, whereas in portions that do not demand as much rigidity, vias may be spaced further apart. The formation of an I-beam has structural properties, including rigidity, torsional strength, and the like, and will not be further described herein, except as may be needed to illustrate the current embodiments.

I-beam 140 is illustrated as including binding to all of copper layers 115 and 125, but this is not necessarily so. In particular, it may be understood that the binding of vias 130, 132, 134, and 136 to only foil copper layers 125 may be sufficient to form a rigid structural member along the side of PCB 100, or it may be desirable to bind additional clad copper layers 115 to the vias to obtain the desired rigidity. In addition to the rigidity provided by I-beam 140, the presence of the I-beam may mitigate heat induced stress on PCB 100. Here, I-beam 140 may be understood to more evenly distribute heat generated in a particular copper layer 115 or 125, or in a particular location of PCB 100 may be more evenly distributed along the edge of the PCB by virtue of the presence of the I-beam. In a particular embodiment, in the fabrication of PCB 100 or a subsequent assembly of components onto the PCB, a solder mask formed on foil layers 125 may be removed, thereby exposing the surface of I-beam 140. Here, during a solder reflow portion of the assembly process, additional solder can be reflowed atop the exposed surface of I-beam 140, thereby thickening, and hence strengthening, the I-beam, as needed or desired.

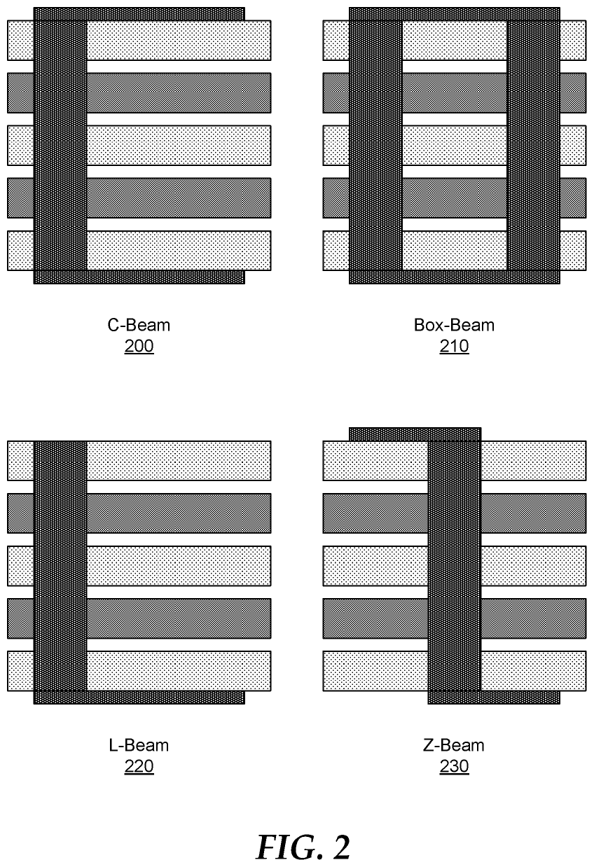

FIG. 2 illustrates profiles of PCBs with various different stiffening structures. A C-beam 200 is illustrated with vias proximate to the edge of the PCB. However, it will be understood that a C-beam may be formed with vias placed further from the edge of the PCB. A box-beam 210 is illustrated with both ends of the foil copper layer connected to vias. An L-beam 220 is illustrated as having the vias connected to only a bottom foil copper layer. However, it will be understood that an L-beam may be formed with a top foil copper layer. Further, L-beam 220 is illustrated with vias proximate to the edge of the PCB. However, it will be understood that an L-beam may be formed with vias placed further from the edge of the PCB. A Z-beam 230 is illustrated herein. In another embodiment, a beam structure is formed as a T-beam structure. Other beam profiles may be utilized, as needed or desired. For example, a stiffening beam structure may be provided by providing a copper cladding or a solder treatment on an edge of a PCB that is connected to the metal layers at the edges to form an E-beam structure, or other edge-stiffened structures, as needed or desired. In another case, rather than single via structures forming a web for a beam structure, a trench can be formed and plated like a via or filled with solder to form a web of a beam structure, as needed or desired.

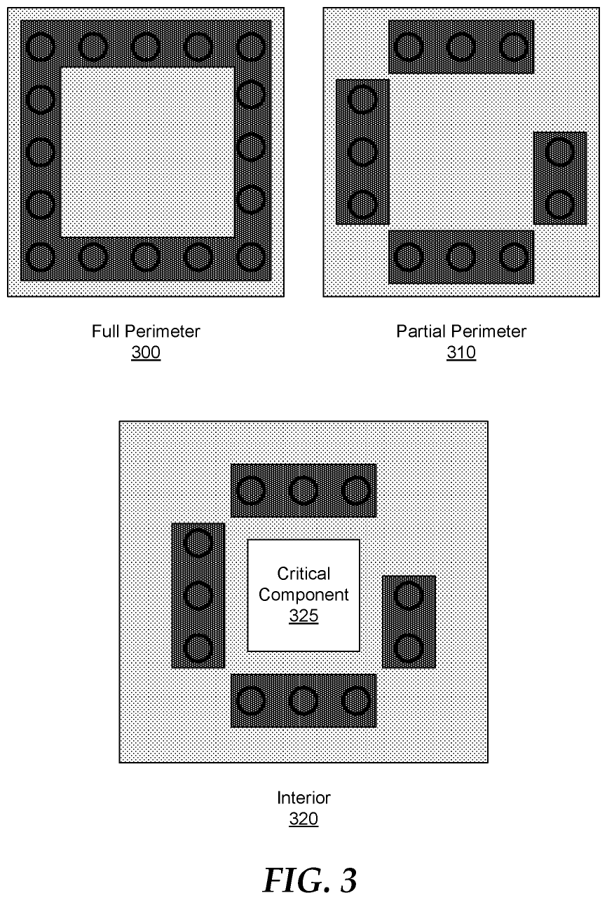

FIG. 3 illustrates top views of PCBs with various different layouts of stiffening structures. A full perimeter stiffening 300 shows a single stiffening structure formed around the entire perimeter of the PCB. A partial perimeter stiffening 310 shows portions of the perimeter of the PCB as including stiffening structures. Here, a determination may be made that various portions of the edge of the PCB may need greater stiffening, while other portions may not need stiffening. An interior stiffening 320 shows various stiffening structures, for example, around a particular component 325, such as a CPU, a memory device, a GPU, or the like. Here, stiffening around component 325 may provide sufficient structural strengthening as to not necessitate stiffening of the edges of the PCB. Other embodiments may have any combination of the layouts as described above. For example, an interior stiffening structure may be utilized in combination with a full perimeter stiffening structure or a partial perimeter stiffening structure, as needed or desired. Note that the stiffening structures illustrated in FIG. 3 may be utilized with any one or more of the stiffening structure profiles as shown in FIGS. 1 and 2, as needed or desired.

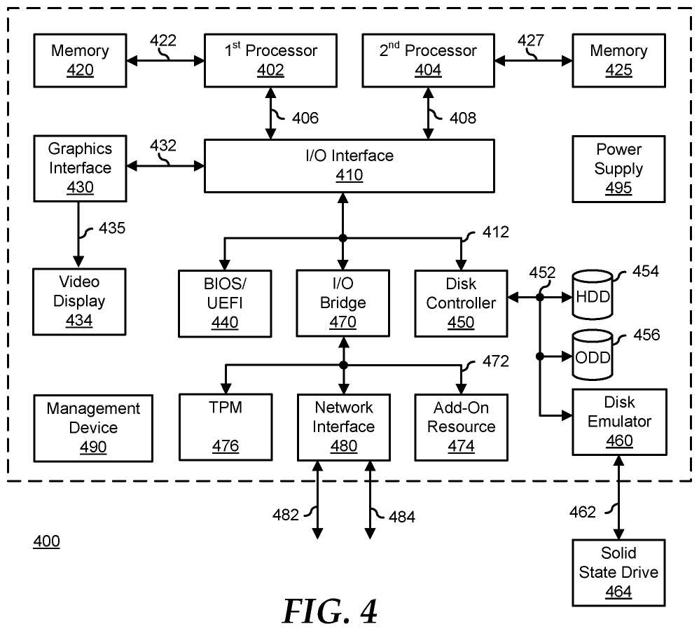

FIG. 4 illustrates a generalized embodiment of an information handling system 400. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 400 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 400 can include processing resources for executing machine-executable code, such as a central processing unit (CPU), a programmable logic array (PLA), an embedded device such as a System-on-a-Chip (SoC), or other control logic hardware. Information handling system 400 can also include one or more computer-readable medium for storing machine-executable code, such as software or data. Additional components of information handling system 400 can include one or more storage devices that can store machine-executable code, one or more communications ports for communicating with external devices, and various input and output (I/O) devices, such as a keyboard, a mouse, and a video display. Information handling system 400 can also include one or more buses operable to transmit information between the various hardware components.

Information handling system 400 can include devices or modules that embody one or more of the devices or modules described below, and operates to perform one or more of the methods described below. Information handling system 400 includes a processors 402 and 404, an input/output (I/O) interface 410, memories 420 and 425, a graphics interface 430, a basic input and output system/universal extensible firmware interface (BIOS/UEFI) module 440, a disk controller 450, a hard disk drive (HDD) 454, an optical disk drive (ODD) 456 , a disk emulator 460 connected to an external solid state drive (SSD) 464, an I/O bridge 470, one or more add-on resources 474, a trusted platform module (TPM) 476, a network interface 480, a management device 490, and a power supply 495. Processors 402 and 404, I/O interface 410, memories 420 and 425, graphics interface 430, BIOS/UEFI module 440, disk controller 450, HDD 454, ODD 456 , disk emulator 460, SSD 364, I/O bridge 470, add-on resources 474, TPM 476, and network interface 480 operate together to provide a host environment of information handling system 400 that operates to provide the data processing functionality of the information handling system. The host environment operates to execute machine-executable code, including platform BIOS/UEFI code, device firmware, operating system code, applications, programs, and the like, to perform the data processing tasks associated with information handling system 400.

In the host environment, processor 402 is connected to I/O interface 410 via processor interface 406, and processor 404 is connected to the I/O interface via processor interface 408. Memory 420 is connected to processor 402 via a memory interface 422. Memory 425 is connected to processor 404 via a memory interface 427. Graphics interface 430 is connected to I/O interface 410 via a graphics interface 432, and provides a video display output 435 to a video display 434. In a particular embodiment, information handling system 400 includes separate memories that are dedicated to each of processors 402 and 404 via separate memory interfaces. An example of memories 420 and 425 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 440, disk controller 450, and I/O bridge 470 are connected to I/O interface 410 via an I/O channel 412. An example of I/O channel 412 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 410 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 440 includes BIOS/UEFI code operable to detect resources within information handling system 400, to provide drivers for the resources, initialize the resources, and access the resources. BIOS/UEFI module 440 includes code that operates to detect resources within information handling system 400, to provide drivers for the resources, to initialize the resources, and to access the resources.

Disk controller 450 includes a disk interface 452 that connects the disk controller to HDD 454, to ODD 456, and to disk emulator 460. An example of disk interface 452 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 460 permits SSD 464 to be connected to information handling system 400 via an external interface 462. An example of external interface 462 includes a USB interface, an IEEE 1394 (Firewire) interface, a proprietary interface, or a combination thereof Alternatively, solid-state drive 464 can be disposed within information handling system 400.

I/O bridge 470 includes a peripheral interface 472 that connects the I/O bridge to add-on resource 474, to TPM 476, and to network interface 480. Peripheral interface 472 can be the same type of interface as I/O channel 412, or can be a different type of interface. As such, I/O bridge 470 extends the capacity of I/O channel 412 when peripheral interface 472 and the I/O channel are of the same type, and the I/O bridge translates information from a format suitable to the I/O channel to a format suitable to the peripheral channel 472 when they are of a different type. Add-on resource 474 can include a data storage system, an additional graphics interface, a network interface card (NIC), a sound/video processing card, another add-on resource, or a combination thereof. Add-on resource 474 can be on a main circuit board, on separate circuit board or add-in card disposed within information handling system 400, a device that is external to the information handling system, or a combination thereof.

Network interface 480 represents a NIC disposed within information handling system 400, on a main circuit board of the information handling system, integrated onto another component such as I/O interface 410, in another suitable location, or a combination thereof. Network interface device 480 includes network channels 482 and 484 that provide interfaces to devices that are external to information handling system 400. In a particular embodiment, network channels 482 and 484 are of a different type than peripheral channel 472 and network interface 480 translates information from a format suitable to the peripheral channel to a format suitable to external devices. An example of network channels 482 and 484 includes InfiniBand channels, Fibre Channel channels, Gigabit Ethernet channels, proprietary channel architectures, or a combination thereof. Network channels 482 and 484 can be connected to external network resources (not illustrated). The network resource can include another information handling system, a data storage system, another network, a grid management system, another suitable resource, or a combination thereof.

Management device 490 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 400. In particular, management device 490 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 400, such as system cooling fans and power supplies. Management device 490 can include a network connection to an external management system, and the management device can communicate with the management system to report status information for information handling system 400, to receive BIOS/UEFI or system firmware updates, or to perform other task for managing and controlling the operation of information handling system 400. Management device 490 can operate off of a separate power plane from the components of the host environment so that the management device receives power to manage information handling system 400 when the information handling system is otherwise shut down. An example of management device 490 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 490 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board (PCB), comprising:
a first metal layer including a first portion; and
a first via coupled to the first metal layer at the first portion, the first portion of the first metal layer forming a first flange of a beam structure in the PCB, and the first via forming a first web of the beam structure in the PCB.

2. The PCB of claim 1, further comprising:
a second metal layer including a second portion, wherein the first via is further coupled to the second metal layer at the second portion, the second portion forming a second flange of the beam structure.

3. The PCB of claim 2, wherein the first metal layer is on a top surface of the PCB and the second metal layer is on a bottom surface of the PCB.

4. The PCB of claim 3, further comprising:
a third metal layer including a third portion, wherein the first via is further coupled to the third metal layer at the third portion, the third portion forming a third flange of the beam structure

5. The PCB of claim 4, wherein the third metal layer is in an interior layer of the PCB.

6. The PCB of claim 3, wherein the beam structure is an I-beam.

7. The PCB of claim 1, further comprising:
a second via coupled to the first metal layer at the first portion.

8. The PCB of claim 7, wherein the second via forms an element of the first web of the beam structure.

9. The PCB of claim 8, wherein the second via forms a second web of the beam structure.

10. The PCB of claim 1, wherein the beam structure includes one of a C-beam, a box beam, a L-beam, a Z-beam, and a T-beam.

11. A method for preventing warping of a printed circuit board (PCB), the method comprising:
fabricating, a first metal layer of the PCB, the first metal layer including a first portion;
fabricating a first via through the PCB; and
coupling the via to the first metal layer at the first portion, the first portion of the first metal layer forming a first flange of a beam structure in the PCB, and the first via forming a first web of the beam structure in the PCB.

12. The method of claim 11, further comprising:
fabricating a second metal layer of the PCB, the second metal layer including a second portion; and
coupling the first via to the second metal layer at the second portion, the second portion forming a second flange of the beam structure.

13. The method of claim 12, wherein the first metal layer is on a top surface of the PCB and the second metal layer is on a bottom surface of the PCB.

14. The method of claim 13, further comprising:
fabricating a third metal layer of the PCB, the third metal layer including a third portion; and
coupling the first via to the third metal layer at the third portion, the third portion forming a third flange of the beam structure.

15. The method of claim 14, wherein the third metal layer is in an interior layer of the PCB.

16. The method of claim 13, wherein the beam structure is an I-beam.

17. The method of claim 11, further comprising:
fabricating a second via through the PCB; and
coupling the third via to the first metal layer at the first portion.

18. The method of claim 17, wherein the second via forms an element of the first web of the beam structure.

19. The method of claim 18, wherein the second via forms a second web of the beam structure.

20. An information handling system, comprising:
a component that generates heat; and
a printed circuit board (PCB) including:
a first metal layer including a first portion; and
a first via coupled to the first metal layer at the first portion, the first portion of the first metal layer forming a first flange of a beam structure in the PCB, and the first via forming a first web of the beam structure in the PCB, wherein the beam structure is formed proximate to the component to prevent warping of the PCB.
